(19) United States
(12) Patent Application Publication
(10) Pub. No.: US 2010/0013033 A1
(43) Pub. Date: Jan. 21, 2010

(54) Enablement of IC devices during assembly

(76) Inventor: Chia-Shing Chou, Oak Park, CA (US)

Correspondence Address: TOPE-MCKAY & ASSOCIATES, 23852 PACIFIC COAST HIGHWAY #311, MALIBU, CA, 90265, US

(21) Appl. No.: 12/218,982

(22) Filed: Jul. 18, 2008

(51) Int. Cl. H01L 21/50; H01L 23/00

(52) U.S. Cl. 257/415; 438/113; 257/678; 438/51; 257/E23.001; 257/E21.499

(57) ABSTRACT

A method for packaging sensitive micro devices and devices formed by the method are presented. The method comprises acts of standard packaging, but with the devices' protective layers remaining intact until before sealing. Three principle acts of the method include (1) singulating the devices into individuals or subsets, (2) attaching the devices with packaging, and (3) hermetically sealing the devices. One may wire-bond the devices as well as remove the sacrificial layer before hermetically sealing. This method is especially useful for micro-electro-mechanical systems (MEMS) whereby the movable components are protected.

### PRIORITY CLAIM

### FIELD OF INVENTION

The present invention relates to an efficient packaging technique for sensitive devices. This technique is particularly useful for the mass packaging on the chip level of micro-electro-mechanical systems (MEMS) in light of their cantilever beams. Specifically, the invention relates to releasing the sacrificial layer after the steps of singulation, attachment with packaging, and optionally wire-bonding, and just before the step of sealing the MEMS.

### BACKGROUND OF INVENTION

The overall process of packaging devices can be hazardous to the function small, movable components. Singulation can create many problems for these movable components, whether through the “diamond saw” method or “scribe and break.”

The “diamond saw” technique, using blades as thin as 2 mils, requires water to cool the device during operation. Two problems arise with this technique after the devices are released: (1) the presence of water can destroy the utility of the electronic device, and (2) the technique creates debris of many small particles.

These particles can wedge themselves under the cantilever beam and cause a worsened device response.

The “scribe and break” technique uses a diamond tool to scribe on the street area (between chips on the wafer). A knife edge is then used to finalize the singulation. This technique, however, creates an uncontrollable number of particles that may become impediments to the movable components. The result is an unacceptable degree of uncertainty in device response.

This singulation is especially a problem for MEMS. The space under the cantilever beams serves as an easy target for small particles. Removal of the sacrificial layer before singulation is thus highly problematic.

Following singulation, the devices are attached to a certain type of packaging chosen to meet the needs of the particular system. Examples of packaging materials include metal, ceramic, and plastic. Metal is often used for microwave multichip modules and hybrid circuits because of its excellent thermal dissipation and electromagnetic shielding. Ceramic packaging is often used when mass and cost are important considerations. Plastic packaging has been widely used by the electronics industry for many years and for almost any application because of their low manufacturing cost, despite some questions of reliability.

For MEMS, the method of attachment to the packaging is the same die attach for most Integrated Circuits (ICs). The main purpose is to allow for a strong mechanical attachment of the device to the package base. The material for connection should be durable, as it must survive temperature changes, moisture, shock, and vibration. In addition, the material must provide a good thermal path between the MEMS and the package base to carry away excess heat. For these reasons, Silicon die is a common choice.

Sensitive micro devices such as MEMS are typically protected with a sacrificial layer. Removal of this layer is called “release.” Releasing the sacrificial layer opens up the device to potential damage, but is necessary for the device to function. Phosphosilicate-glass (PSG) and Aluminum are typical materials for the sacrificial layer, although it is also desirable to use PECVD (Plasma Enhanced Chemical Vapor Deposition) oxide. The sooner in the device packaging process one releases the sacrificial layer, the sooner the device is exposed to potential harm. Though MEMS are used as the primary example in this work, one can also package materials using this method that do not have a sacrificial layer, such as high electron mobility transistor (HEMT) devices and MMIC (Monolithic Microwave Integrated Circuits) made of HEMTs. These devices and circuits have an air bridge connection that is also sensitive to the surrounding environment and foreign objects.

MEMS are lastly hermetically sealed to protect the device from the environment and downstream contamination.

What is needed is a method to maximally protect the devices during packaging.

### SUMMARY OF INVENTION

The present invention relates to a method of packaging devices in such a way as to minimize risk to the sensitive components of the devices. One may use this method in particular to protect the movable components of a micro-electro-mechanical system (MEMS).

The method comprises acts including: singulating the devices into subsets, attaching the device with packaging, and sealing the device. In addition, one may optionally wire-bond the device to circuitry. Additionally, one may release a movable component before sealing the device. The packaging can be chip-level packaging.

The present invention also includes packaged devices formed according to the method above.

Additionally, the method can be used to package MEMS devices. The release for a MEMS device involves removing the sacrificial layer from a cantilever beam. The MEMS device could also be one of many components in a module.

The present invention also relates to a packaged MEMS device according to the method described above.

### BRIEF DESCRIPTION OF THE DRAWINGS

The objects, features and advantages of the present invention will be apparent from the following detailed descriptions of the various aspects of the invention in conjunction with reference to the following drawings, where:

FIG. 1A is an illustration showing a top-level perspective schematic view of a sensitive micro device, in particular a MEMS device;

FIG. 1B is an illustration showing a schematic, cross-sectional side view of a MEMS device, with movable device (cantilever beam) shown in the “open” position;

FIG. 1C is an illustration showing a schematic, cross-sectional side view of a MEMS device, with movable device (cantilever beam) shown in the “closed” position; and

FIG. 2 is an illustration showing a flowchart of the acts of the method for packaging devices described herein.

### DETAILED DESCRIPTION

The present invention provides a method to package devices so as to reduce risk to the device's function. The following description is presented to enable one of ordinary skill in the art to make and use the invention and to incorporate it in the context of particular applications. Various modifications, as well as a variety of uses in different applications will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of the present invention. However, it will be apparent to one skilled in the art that the present invention may be practiced without necessarily being limited to these specific details. In other instances, well-known structures and devices are shown in block diagram form, rather than in detail, in order to avoid obscuring the present invention.

The reader's attention is directed to all papers and documents which are filed concurrently with this specification and which are open to public inspection with this specification, and the contents of all such papers and documents are incorporated herein by reference. All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features. Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the claims herein is not intended to invoke the provisions of 35 U.S.C. 112, Paragraph 6.

Before describing the invention in detail, first a glossary of terms used in the description and claims is provided. Next, a description of various principal aspects of the present invention is provided. Subsequently, an introduction provides the reader with a general understanding of the present invention. Finally, details of the present invention are provided to give an understanding of the specific aspects.

(1) Glossary

Before describing the specific details of the present invention, a glossary is provided in which various terms used herein and in the claims are defined. The glossary provided is intended to provide the reader with a general understanding of the intended meaning of the terms, but is not intended to convey the entire scope of each term. Rather, the glossary is intended to supplement the rest of the specification in more accurately explaining the terms used.

Singulation—The term “singulation” as used with respect to this invention generally indicates separating a device from other like devices. One can singulate one device or a set of devices from another set of devices.

Attachment—The term “attachment” as used with respect to this invention generally indicates die attaching the device to packaging.

Sacrificial layer—The term “sacrificial layer” as used with respect to this invention generally indicates a protective layer around the movable part of a MEMS device.

Seal—The term “seal” as used with respect to this invention generally indicates a final hermetic seal attaching to the packaged device. This is also the final step in packaging.

(2) Principal Aspects

The present invention has three “principal” aspects. The first is singulation. The singulation separates the desired device(s) from other devices. The second aspect is attachment, performed to attach the device(s) to the packaging. The third is hermetically sealing the device(s). These aspects will be described in more detail below.

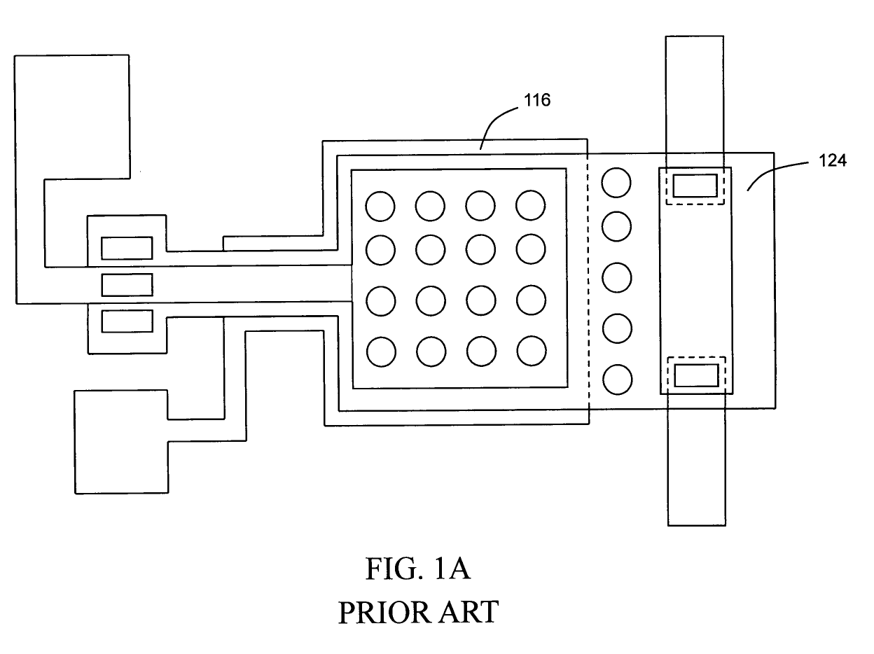

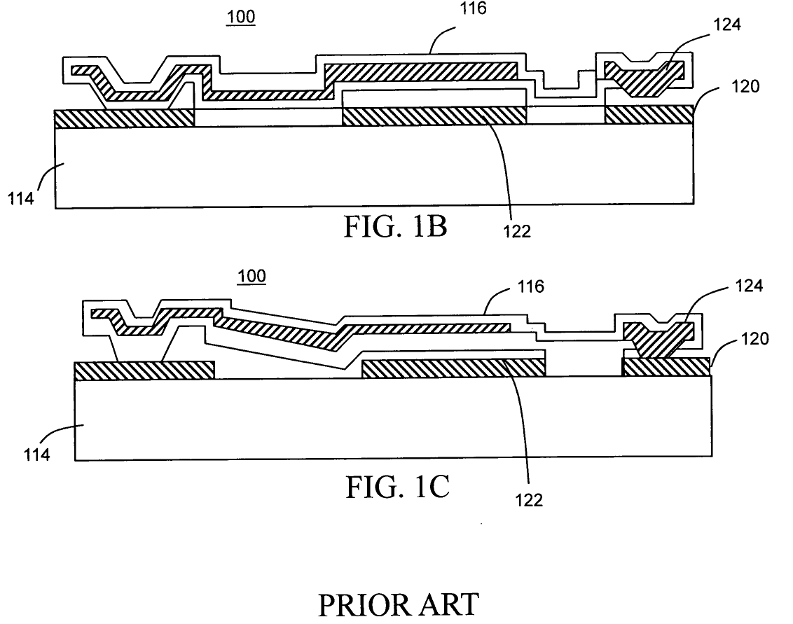

A diagram of a non-limiting example to a device that can benefit from the packaging method as described here is provided in FIG. 1. The device depicted is a micro-electro-mechanical system with a cantilever beam (116 and 124) fabricated on a substrate 114. It is this cantilever beam that can be compromised by damage from the environment or small particles created by singulation. FIG. 1B shows the MEMS device in the “open” position with 116 separated from 122 and 124 separated from 120. In the “closed” position, as in FIG. 1C, 116 is in contact with 122, and 124 is in contact with 120. The ease of this transition is related to the response of the MEMS device. This response is inhibited when particles are wedged between the beam and the base or when the beam has sustained damage from the environment, such as water used to cool the diamond saw.

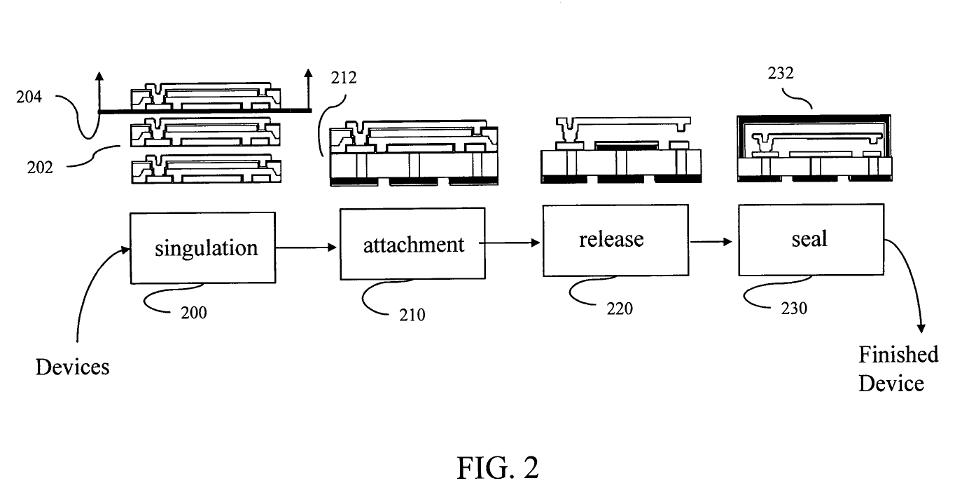

A block diagram depicting the packaging method of the present invention is provided in FIG. 2. While any sensitive micro device may be packaged in this method, a MEMS device is shown as the non-limiting example. The devices are first singulated at 200 from the original group 202 with a singulation method 204 into individuals or subsets. Singulation can be done via the “diamond saw” method or “scribe and break” as described in the background section. Though both methods have their strengths and weaknesses, the “scribe and break” method is optimal as it is efficient for mass production. The device is next attached at 210 with the packaging 212. The MEMS is die attached with a chip-level packaging approach by die attachment as done in ICs. Chip-level packaging has been the industry standard for many years and thus can reliably be used. Next, the device can be released at this point 220 if necessary, such as for a MEMS device. While many different materials are available for a sacrificial layer, PECVD oxide is used. Any material that has a large differential wet or dry etch rate with respect to the structural material can be used. Examples include, but are not limited to PSG, Aluminum, Copper and organic materials such as photo resist. If desired, one may also wire-bond the attached device to other circuitry at this point or before the release (not pictured). Lastly, the device is sealed at 230 in a hermetic seal 232.

What is claimed is:

1. A method for packaging devices comprising acts of:
singulating a set of devices into singulated device subsets;
attaching a singulated device subset with packaging; and
sealing the packaged device subset.

2. A method for packaging devices as set forth in claim 1, further comprising an act of: wire-bonding the device to the packaging or the device subset to circuitry before sealing.

3. A method for packaging devices as set forth in claim 1, further comprising an act of: releasing a movable component attached to the packaged device subset before sealing.

4. A method for packaging devices as set forth in claim 1, wherein the packaging is chip-level packaging.

5. A packaged device formed by the method of claim 1.

6. A method for packaging devices as set forth in claim 1, wherein the devices are micro-electro-mechanical systems (MEMS).

7. A method for packaging MEMS as set forth in claim 6, further comprising an act of releasing a movable component before sealing.

8. A method for packaging MEMS as set forth in claim 7, wherein the movable component is a cantilever beam.

9. A method for packaging MEMS as set forth in claim 6, wherein the MEMS device is one of many components in the module.

10. A packaged MEMS device formed by the method of claim 6.
